(19) United States
(12) Patent Application Publication
(10) Pub. No.: US 2001/0025989 A1
(43) Pub. Date: Oct. 4, 2001

(54) Semiconductor device and method of manufacturing the same

(76) Inventors: Katsuyoshi Shibuya, Miyagi (JP); Takeharu Asano, Miyagi (JP); Satoru Kijima, Miyagi (JP); Katsunori Yanashima, Kanagawa (JP); Motonobu Takeya, Miyagi (JP); Masao Ikeda, Kanagawa (JP); Tomonori Hino, Miyagi (JP); Takashi Yamaguchi, Kanagawa (JP); Shinro Ikeda, Miyagi (JP); Osamu Goto, Miyagi (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 09/758,205

(22) Filed: Jan. 12, 2001

(30) Foreign Application Priority Data
Jan. 13, 2000 (JP) P2000-010058
Dec. 8, 2000 (JP) P2000-404035

(51) Int. Cl. H01L 27/01; H01L 27/12

(52) U.S. Cl. 257/347

(57) ABSTRACT

To provide a semiconductor device capable of enhancing crystallinity of a semiconductor of a III-V group compound of a nitride system formed on a sapphire substrate and to provide a method of manufacturing the same.

On the sapphire substrate, after forming a seed crystal layer having a crystalline part and an opening part made of a crystal of the semiconductor of the III-V group compound of the nitride system, a concave part communicatively connected to the opening part is formed within the substrate. Then, an n-side contact layer is grown from the crystalline part. Since the lateral grown crystal and the sapphire substrate does not contact, in the n-side contact layer and the crystal of the semiconductor of the III-V group compound of the nitride system grown thereon, density of penetration dislocation restricts lower and a crystal orientation less changes.

### BACKGROUND OF THE INVENTION

1. Field of the Invention

The present invention relates to a semiconductor device having a semiconductor layer made of a semiconductor of a III-V group compound of a nitride system and a method of manufacturing the same.

2. Description of the Related Art

The semiconductor of the III-V group compound of the nitride system such as GaN mixed crystal, AlGaN mixed crystal or GaInN mixed crystal is a direct transition semiconductor material and having a characteristic such that its forbidden band width spreads 1.9 eV to 6.2 eV. Hence, these semiconductor of the III-V group compound of the nitride system can be obtained light emission from visible range to ultra violet range so that it is noteworthy for a material making of a semiconductor laser diode (LD) or a light emitting diode (LED). In addition, it is also noteworthy for a material making of an electric device because its saturation electron speed and a break-down field is large.

In general, these semiconductor devices has a structure such that semiconductor layers of the III-V group compound of the nitride system are stacked, and the semiconductor of the III-V group compound of the nitride system is grown on a substrate with a chemical vapor deposition method such as a MOCVD (Metal Organic Chemical Vapor Deposition) method. As for a substrate, typically, a sapphire substrate (Al₂O₃) is employed. However, between sapphire and the semiconductor of the III-V group compound of the nitride system, there is lattice mismatch, or considerable difference in thermal expansion coefficient, which generates crystal defects such as dislocation so as to decrease distortion in the semiconductor layers of the III-V group compound of the nitride system. Among such crystal defects, penetration dislocation is most harmful because it causes damage to optical and electrical characteristics of the semiconductor device. Penetration dislocation is a defect such that a dislocation defect is propagated in a thickness direction of the layers and becomes a center of non-radiative recombination and parts where a current leaks. Non-radiative recombination is a defect such that even if electrons and holes recombine each other, radiation does not occur.

For the above-mentioned reasons, in recent years, it is suggested that a method decreases penetration dislocation density by means of a lateral growth from a seed crystal. This method is a technique such that an opening such as a trench is formed in the crystal of the semiconductor of the III-V group compound of the nitride system, which becomes the seed crystal provided on the substrate in order to grow crystal in a lateral direction from a side wall surface corresponding to the opening of the seed crystal.

However, conventionally in a case of using this technique, the opening is formed in a manner that etching is performed to an interface between the sapphire substrate and the semiconductor of the III-V group compound of the nitride system, so that it causes a problem that a lateral grown crystal from the seed crystal and the substrate are like to contact each other. In case that the seed crystal and the substrate contact, which changes a crystal orientation, or propagates defects generated from a contact part to a top surface. Because of this, even if in a lateral growth region, which is typically excellent in crystallinity, a lot of dislocation defects exist and degrades crystallinity. As a result of this, density of crystal defects in an active region becomes high, and optical and electrical characteristics of the semiconductor device is degraded, which may result in loosing its reliability.

In addition, in MRS Internet J. Nitride Semicond. Res. 4S1, G3.38 (1999) discloses that a silicon carbide substrate is etched in a case that the semiconductor of the III-V group compound of the nitride system is grown on silicon carbide capable of being a substrate in a similar manner as sapphire. Yet, an example of such a sapphire substrate treated in the same way as a substrate of the semiconductor device using the semiconductor of the III-V group compound of the nitride system, has not been reported. Silicon carbide is a material etched with RIE (Reactive Ion Etching) using tetrachloride fluoride carbon gas (CF₄) easily.

Other and further objects, features and advantages of the invention will appear more fully from the following description.

### SUMMARY OF THE INVENTION

The invention has been achieved in consideration of the above problems and its object is to provide a semiconductor device which can enhance crystallinity of a semiconductor of a III-V group compound of a nitride system formed in a sapphire substrate and to provide a method of manufacturing the same.

A semiconductor device according to the present invention includes a semiconductor layer made of a semiconductor of a III-V group compound of a nitride system containing at least one kind element among a III group element and nitride among a V group element on a side of a substrate made of sapphire. The semiconductor includes a first crystal layer having a crystalline part and an opening part made of a crystal of the semiconductor of the III-V group compound of the nitride system and a second crystal layer provided in a manner of covering the crystalline part of the first crystal layer, and the substrate includes a concave part in a region corresponding to the opening part of the first crystal layer.

In a method of manufacturing a semiconductor device formed by growing a semiconductor of a III-V group compound of a nitride system containing at least one kind element among a III group element and nitride (N) among a V group element according to the present invention comprises steps of forming a growth layer by growing the crystal of the semiconductor of the III-V group compound of the nitride system on the substrate, forming a first crystal layer having a crystalline part and an opening part by selectively removing the growth layer in order to an opening forming a concave part communicatively connected to the opening part on the substrate by selectively removing a region corresponding to the opening part of the first crystal layer of the substrate, and forming a second crystal layer by growing the crystal of the semiconductor of the III-V group compound of the nitride system from the crystalline part of the first crystal layer.

In a semiconductor device according to the present invention, a concave part is provided in a region corresponding to an opening part of a first crystal layer in a substrate made of sapphire, so that a semiconductor layer is excellent in crystallinity.

In a method of manufacturing a semiconductor device according to the present invention, a first crystal layer is formed by forming an opening in a growth layer provided on a substrate made of sapphire, and in a substrate, a region corresponding to the opening is removed in order to a concave part communicatively connected to the opening in the substrate. Then, a second crystal layer is formed.

### BRIEF DESCRIPTION OF THE DRAWINGS

These and other objects and features of the present invention will become clear from the following description of the preferred embodiments given with reference to the accompanying drawings, in which:

FIG. 1 is a section view describing a method of manufacturing a semiconductor laser diode relative to a first embodiment of the present invention;

FIG. 2 is a section view describing a manufacturing process following to FIG. 1;

FIG. 3A is a section view describing a manufacturing process following to FIG. 2;

FIG. 3B is a view schematically showing a state where penetration dislocation is generated in the manufacturing process of FIG. 3A;

FIG. 4 is a view schematically showing a state where penetration dislocation is generated when manufacturing a conventional semiconductor laser diode;

FIG. 5 is a section view describing a manufacturing process following to FIG. 5 and shows a main part of the semiconductor laser diode relative to a first embodiment of the present invention;

FIG. 6A is a view schematically showing light emission intensity of the semiconductor laser diode shown in FIG. 5;

FIG. 6B is a view schematically showing light emission intensity of a conventional semiconductor laser diode.

FIG. 7 is a section view describing advantages of appropriatly selecting the crystalline part and a width of the opening part the semiconductor laser diode shown in FIG. 5;

FIG. 8 is a locking curb obtained by an X-ray diffraction of a semiconductor laser diode achieved in Example 1 of the present invention;

FIG. 9 is a locking curb obtained by an X-ray diffraction of a semiconductor laser diode achieved in Example 2 of the present invention;

FIG. 10 is a locking curb obtained by an X-ray diffraction of a semiconductor laser diode achieved in Example 3 of the present invention;

FIG. 11 is a locking curb obtained by an X-ray diffraction of a semiconductor laser diode achieved in Comparative example;

FIG. 12 is a picture taken with SEM showing a state of a crystal in the n-side contact layer of the semiconductor laser diode achieved in Example 3 of the present invention;

FIG. 13 is a section view showing a configuration of a semiconductor laser diode relative to a modification of the semiconductor laser diode shown in FIG. 13.

### DETAILED DESCRIPTION OF THE PREFERRED EMBODIMENTS

Embodiments of the invention will be described in detail hereinbelow by referring to the drawings.

[First embodiment]

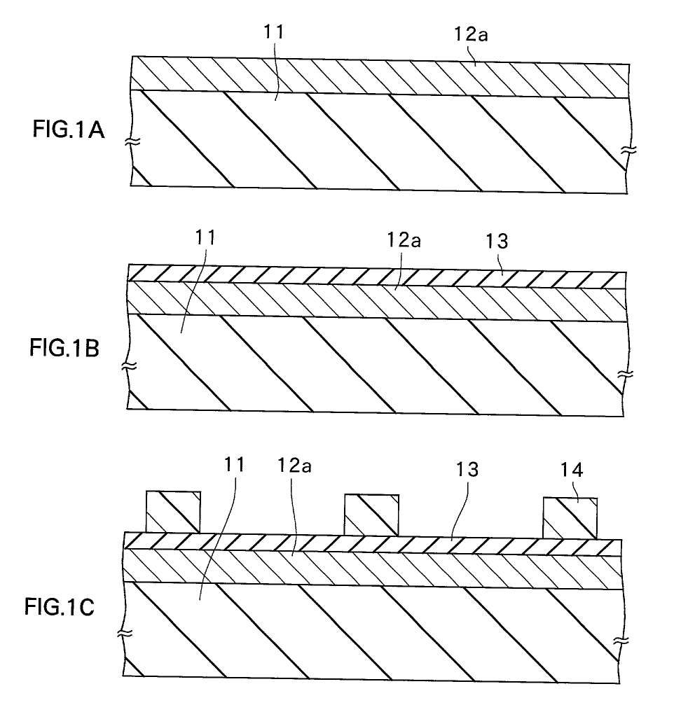

First, referring to FIGS. 1 to 5, a method of manufacturing a semiconductor laser diode 1 as a semiconductor device relative to a first embodiment of the present invention will be described. Additionally, the semiconductor laser diode 1 relative to the embodiment of the present invention will be also described since it is embodied by the method of manufacturing the semiconductor laser diode of the embodiment.

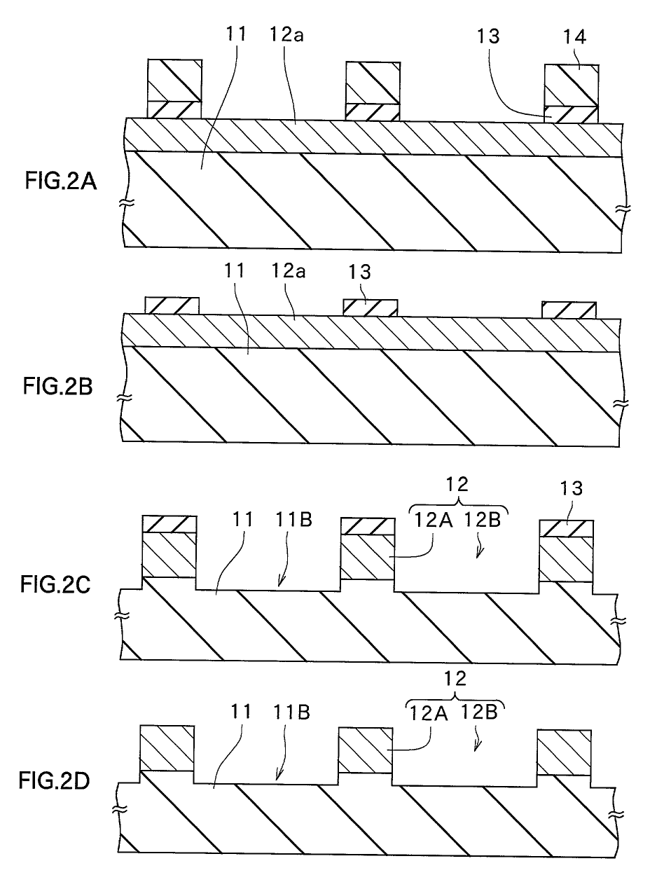

In the embodiment, as shown in FIG. 1, a sapphire substrate 11 is prepared. With a MOCVD method, the crystal of a semiconductor of a III-V group compound of a nitride system is grown on a c face of the sapphire substrate 11 to form a growth layer 12a for a seed crystal layer in order to form a seed crystal layer 12 mentioned after (See FIG. 2B). Here, the semiconductor of a III-V group compound of a nitride system is a material containing at least one kind element among a III group element such as gallium (Ga), aluminum (Al), boron(B) or indium (In), and nitride (N) among a V group. For instance, in the embodiment, undope-GaN is grown about 2 μm. The MOCVD method can be performed in any of atmospheres: an atmospheric atmosphere, a low pressure atmosphere, and a high pressure atmosphere. However, for obtaining good quality crystal, the high pressure atmosphere is best choice.

Following this, as shown in FIG. 1B, for example, with a CVD (Chemical Vapor Deposition) method, an insulating film 13 made of silicon nitride (Si₃N₄) or silicon dioxide (SiO₂) is formed. The insulating film 13 may be formed as a multilayered structure of a silicon nitride layer and a silicon dioxide layer.

Then, as shown in FIG. 1C, on the insulating film 13, a photoresist film 14 is formed and a plurality of stripe-shaped patterns disposed with a predetermined interval in <1-100> directions of the growth layer 12 a for a seed crystal layer (that is, <11-20> directions of the sapphire substrate 11). Here, <1-100> represents by adding “⁻” in front of numerals for convenience in writing, although it generally represents by drawing an line over numerals. <11-20> represents in a similar manner. Hereinafter, in case of showing the same expression, it will represent in a like manner.

As shown in FIG. 2A, RIE (Reactive Ion Etching) is performed with the photoresist film 14 as a mask to remove the parts of the insulating layer 13, which are not covered with the photoresist film 14. After this, as shown in FIG. 2B, the photoresist film 14 is removed.

Further, as shown in FIG. 2C, RIE using chlorine gas as etching gas is performed with the insulating film 13 as a mask to remove the parts of the growth layer 12a for a seed crystal layer, which are not covered with the insulating film 13. Thereby, the growth layer 12a for a seed crystal layer turns a seed crystal layer having a crystalline part 12A and an opening part 12B. Here, the crystal layer 12 corresponds to a specific example of a first crystal layer of the present invention.

Further, RIE is performed with the insulating film 13 as a mask to remove the parts of the sapphire substrate 11, which are not covered with the insulating film 13. Specifically, for instance, using chlorine gas as etching gas, it is performed under condition such that substrate temperature is set at 0° C., and pressure is set 0.5 Pa. This forms a concave part communicatively connected to the opening part 12B in the sapphire substrate 11. In the sapphire substrate 11, etching can be performed successively with etching in the growth layer 12a for a seed crystal layer, or can be performed as another step.

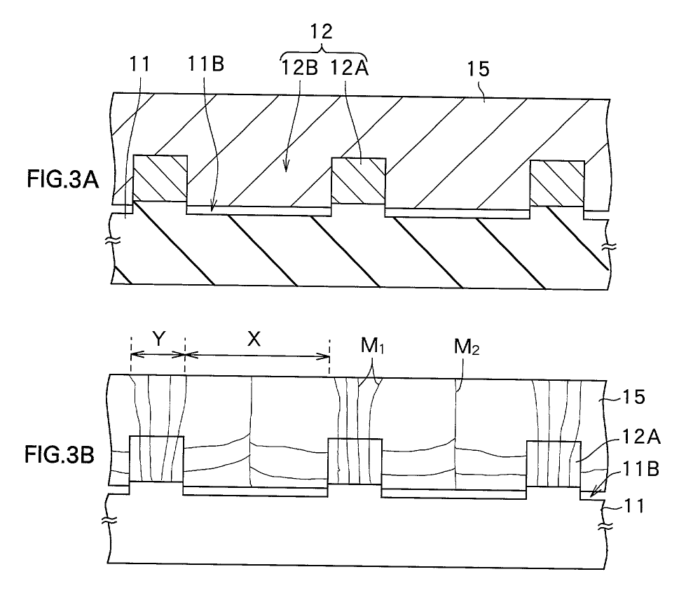

A depth of the concave part 11B in the sapphire substrate 11 is preferably equal to or more than 100 nm, more preferably, equal to or more than 200 nm. As the reason of determining such a depth, when forming an n-side contact layer 15 described after (see FIG. 3A), such a depth can prevent effectively that a grown crystal and the sapphire substrate 11 contact each other. Furthermore, the depth of the concave part 11B is preferable within a range of equal to or more than 200 nm, and more preferably, to equal to or less than 1000 nm. Because unlike silicon carbide, sapphire is a material, which is hard to process etching so that a high manufacturing cost is made if etching is performed more than needed. As for the above-mentioned depth of the concave part 11B, an error resulting from measurement accuracy is not taken into consideration. Therefore, a preferable depth is the above described value including an error of ±20 nm resulting from measurement accuracy.

After forming the concave part 11B in the sapphire substrate 11, as shown in FIG. 2D, etching is performed with an etching agent using an aqueous solution doped hydrogen fluoride (HF) to remove the insulating film 13.

Following this, as shown in FIG. 3A, with the MOCVD method, a crystal of n-type GaN doped silicon (Si) as n-type impurity is grown about 4 μm to form the n-side contact layer 15. At this moment, crystal growth of GaN develops from a side wall surface corresponding to a top surface of the crystalline part 12A and the opening part 12B, and also develops in a lateral direction. A growth speed from the side wall surface of the crystalline part 12A is faster than that from the top surface, and after lapse of a certain time, the crystal of GaN grown from the side wall surface spreads, thereby flattening a growth surface. In the embodiment, the concave part 11B is provided in the sapphire substrate 11, which can prevent defects caused by the contact between the lateral grown crystal and the sapphire substrate 11 as described before. Additionally, it can prevent change of a crystal orientation. In case that the concave part 11B is not provided in, each lateral grown crystal does not meet, therefore, substantially, a flat surface can not be obtained. There is a case such that a lateral crystal growth from the crystalline part 12A slightly develops a side of the sapphire substrate 11 rather than a just-lateral direction. Even in such a case, if the depth of the concave part 11B is determined as equal to or more than 100 nm, the contact between a crystal and the sapphire substrate 11 can be prevented effectively. Here, the n-side contact layer 15 corresponds to a specific example of a second crystalline layer of the present invention.

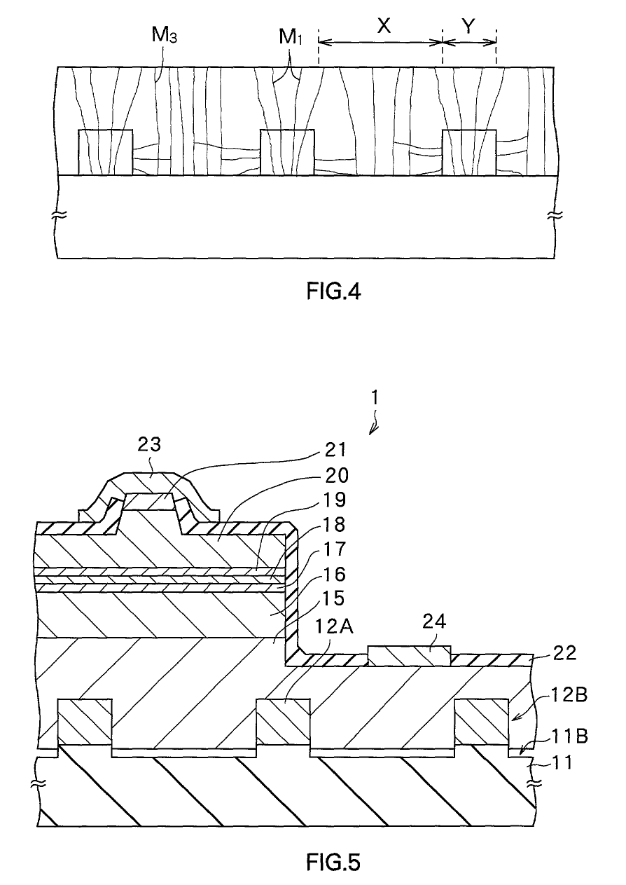

FIG. 3B is a view schematically showing a state where penetration dislocation is generated when forming the n-side contact layer 15. In a region Y over the crystalline part 12A of the n-side contact layer 15, penetration dislocation M₁ from the seed crystal layer 12 (the crystalline part 12A) is propagated, however, in other regions except the above-mentioned region, penetration dislocation M₁ from the seed crystal layer 12 is bent so that it hardly exists (a lateral growth region X). That is, penetration dislocation M₃ attributing by a contact between a lateral grown crystal and the sapphire substrate does not exist unlike a conventional case where an n-side contact layer is grown from a seed crystal layer on the sapphire substrate, which is not provided a concave part shown in FIG. 4. Penetration dislocation M₂ shown in FIG. 3B is generated by meeting the lateral grown crystal from two side wall surfaces opposed to the crystalline part 12A in a meeting part. The meeting part is positioned in a general center of the lateral growth region X corresponding to the concave part 11B and the opening part 12B, that is, penetration dislocation M₂ is also positioned in a general center of the lateral growth region X.

In general, a quality of the lateral grown crystal from the seed crystal layer 12 is better than that of a grown crystal without the seed crystal layer 12. For this reason, even in case that the n-side contact layer is formed thin, a good quality crystal can be achieved. If the thin n-side contact layer 15 can be formed, it prevents bowing of the sapphire substrate 11 due to lattice mismatch or difference of thermal expansion coefficient between sapphire and the semiconductor of the III-V group compound of the nitride system.

After forming the n-side contact layer 15, as shown in FIG. 5, with the MOCVD method, layers are grown sequentially on the n-side contact layer 15. Such layers are: an n-type clad layer 16 made of n-type AlGaN mixed crystal doped silicon as n-type impurity, an n-type guide layer 17 made of n-type GaN doped silicon as n-type impurity, an active layer 18 made of undope-GaInN, a p-type guide layer 19 made of p-type GaN doped magnesium (Mg) as p-type impurity, a p-type clad layer 20 made of p-type AlGaN mixed crystal doped magnesium as p-type impurity and a p-side contact layer 21 made of p-type GaN doped magnesium as p-type impurity.

When the MOCVD method is performed. Trimethylgallium ((CH₃)₃Ga) is employed as a source gas of gallium, trimethylaluminum ((CH₃)₃Al) is employed as a source gas of aluminum, trymethylindium ((CH₃)₃In) is employed as a source gas of indium, ammonia (NH₃) is employed as a source gas of nitride, monosilane (SiH₄) is employed as a source gas of silicon, and bis═cycropentadienyl magnesium ((C₅H₅)₂Mg) is employed as a source gas of magnesium.

After growing the p-side contact layer 21, etching is performed on a part of the p-side contact layer 21, the p-type clad layer 20, the p-type guide layer 19, the active layer 18, the n-type guide layer 17, the n-type clad layer 16 and the n-side contact layer 15 to expose the n-type contact layer 15 on a surface. Following this, an unillustrated mask is formed. With this mask, a part of the p-side contact layer 21 and the p-type clad layer 20 is selectively etched with RIE, thereby forming the p-side contact layer 21 in a narrow belt shape (a ridge shape) whose width is, for example, 2.5 μm. In this case, after being grown, the p-side contact layer 21 is shaped in a narrow best shape, and then, the n-side contact layer 15 may be exposed. The region shaped in a narrow belt shape is a part corresponding to a radiative range of the active layer 18. That is, an unillustrated mask is formed in a manner to correspond to the opening part 12 where dislocation density is low, specifically to correspond to a region corresponding to a region between the crystalline part 12A and the meeting part. In the crystalline part 12A, penetration dislocation M₂ (see FIG. 3B) does not exist. After this, the radiative part is formed in the above-mentioned region, which can achieve device characteristics of the semiconductor laser diode 1.

Following this, on whole exposed surfaces, with a deposition method, an insulating layer 22 made of silicon dioxide is formed. Then, on the insulating layer 22, an illustrated resist film is formed. With RIE, in the resist film, the a region corresponding to the above-mentioned ridge shape is selectively removed to expose the p-side contact layer 21 on a surface and regions except a surface of the p-side contact layer 21 are covered with the insulating film 22.

After this, on a surface and in a vicinity of the p-side contact layer 21, palladium, platinum and gold are sequentially deposited to form a p-side electrode 23. An opening is formed over a region where the n-side contact layer 15 of the insulating layer 22. Titanium, aluminum, and platinum and gold are sequentially deposited to the opening to form an n-side contact layer 24. Then, the sapphire substrate 11 is ground in a manner to be 80 μm thickness, for example. Finally, the sapphire substrate 11 is cleaved in a predetermined width perpendicular to a longitudinal direction of the p-side electrode 23. An unillustrated reflective mirror is formed therein, thereby completing the semiconductor laser diode 1.

Next, the work of the semiconductor laser diode 1 manufactured as described above will be explained.

In the semiconductor laser diode 1, a predetermined voltage is placed between the p-side electrode 23 and the n-side electrode 24, and a current is implanted into the active layer 18, which occurs radiation due to electron-hole recombination. Here, the concave part 11B is provided in the sapphire substrate 11, whereby density of penetration dislocation M₁ restricts lower except a region over the crystalline part 12A of the sapphire substrate 11 (that is, the lateral growth region X corresponds to the concave part 11B). Thereby, degradation caused by application of voltage is hardly occurred, a rise of operating current caused by use is controlled, which results in long device life. In addition, light emission intensity becomes increased.

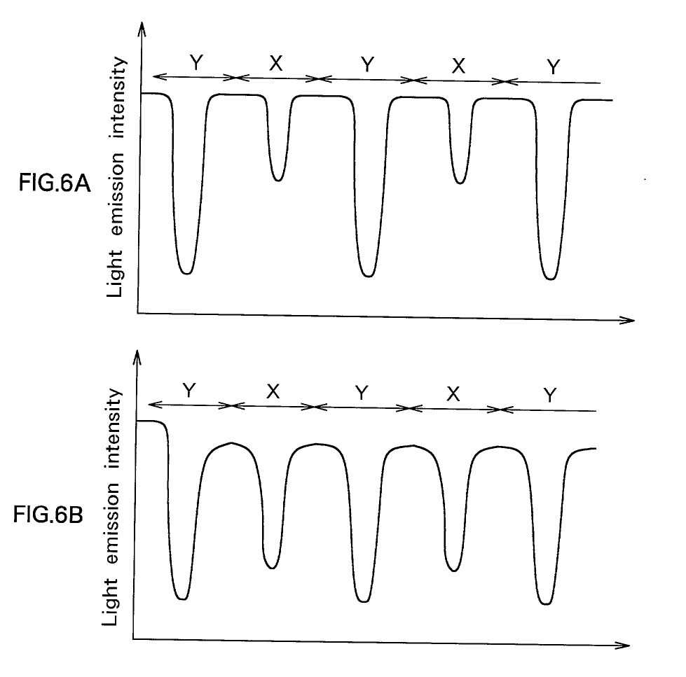

FIG. 6A is a view schematically showing light emission intensity caused by photo luminescence of the semiconductor laser diode 1 of the embodiment. FIG. 6B is a view schematically showing light emission intensity caused by photo luminescence of the semiconductor laser diode, which is not provided with the concave part. In FIGS. 6A and 6B, a vertical axis represents light emission intensity of photo luminescence, and a lateral axis represents corresponding to a lateral coordinate of a cross sectional view of the semiconductor laser diode 1 shown in FIG. 5. As understood from FIGS. 6A and 6B, in the semiconductor laser diode 1 of the present embodiment, compared with a conventional laser diode, its light emission intensity less decreases in the meeting part where each lateral crystal grown from the crystalline part 12A meets each other. Additionally, light emission intensity is relatively stronger in regions within the opening part 12B except the meeting part. This is caused by the reason that crystallinity in the radiative range is enhanced, then the ratio of non-radiative recombination decreases. Recombination is a phenomenon that if recombination between an electron and a hole caused by penetration dislocation M₃ is occurred, radiation is not generated.

According to the method of manufacturing the semiconductor laser diode 1 relative to the embodiment as described before, after providing the concave part 11B commutatively connected to the opening part 12B of the seed crystal layer 12 in the sapphire substrate 11, the n-side contact layer 15 is grown so that the lateral crystal grown from the crystalline part 12A and the sapphire substrate 11 does not contact each other, thereby density of penetration dislocation restricts lower, and a crystal orientation less changes in the n-side contact layer 15, and the layers formed thereon: the n-type clad layer 6, the n-type guide layer 17, the active layer 18, the p-type guide layer 19, the p-type clad layer 20 and the p-side contact layer 21. This prevents degradation caused by application of voltage, which can gain long life in the achieved semiconductor laser diode 1. Additionally, the ratio of non-radiative combination caused by penetration dislocation and the like can decrease and light emission efficiency can be enhanced.

[Second embodiment]

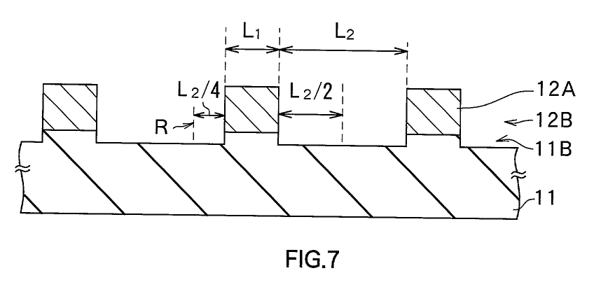

A second embodiment of the present invention relates to a semiconductor laser diode as the semiconductor device and a method of manufacturing the same. A structure of the semiconductor laser diode and a method of manufacturing the same are the same as that of the first embodiment. Here, it will be explained by referring FIG. 7 that the length in a width direction of a crystalline part of seed crystal layer and an opening part (hereinafter it just calls a width) are selected appropriately to achieve a semiconductor laser diode more excellent in device characteristics. In FIG. 7, the same configurations have the same reference numerals of the first embodiment and the detailed explanation will be omitted here.

In the seed crystal layer 12, it is preferable that a width L₁ of the crystalline part 12A shown in FIG. 7 is less than 4 μm, and a width L₂ of the opening part 12B is equal to or less than 12 μm. The width L₁ of the crystalline part 12A is preferable within a range of 2 μm to 4 μm. The width L₂ of the opening part 12B is preferable within a range of 8 μm to 12 μm. In addition, the range of 8 μm to 12 μm includes 12 μm. Specifically, the seed crystal layer 12 can be comprised of the crystalline part 12 A whose width L₁ is 3 μm and the opening part 12B whose width L₂ is 9 μm.

As for the reason that the width L₂ of the opening part 12B is equal to or less than 12 μm, if it is more than 12 μm, each of the lateral crystal grown from the side wall surface of the crystalline part 12A meets, thereby it takes time to be flattened a grown surface of the n-side contact layer 15 or a flat grown surface can not be obtained. The preferable reason that the width L₂ of the opening part 12B is more than 8 μm as follows. As described in the first embodiment, for maintaining and enhancing device characteristics of the semiconductor laser diode 1, it is necessary that a ridge shape (laser stripe) corresponding to the radiative region formed in a part where dislocation density restricts lower (the width L₂/2 in FIG. 7). However, penetration dislocation M₂ (see FIG. 3B) generated by meeting the lateral crystal grown from the crystalline part 12A exists in a general center of the width L₂ of the opening part 12, therefore, it is preferable that a radiative range is provided in half of a part from a boundary surface to the width L₂ of the opening part 12B. The boundary surface is located between the opening part 12B and the crystalline part 12A. The width of the radiative range is within a range of 2 μm to 3 μm, whereby the width L₂ of the opening part 12 is preferably determined as more than 8 μm in order to provide the above-mentioned radiative range in a region where penetration dislocation M₂ does not exist, more preferably in a region corresponding to quarter of a part of the width L₂ of the opening part 12 (L₂/4) shown as reference R in FIG. 7 or in its vicinity.

On the other hand, the reason that the width of the crystalline part 12A is determined as less than 4 μm as follows. If it is more than 4 μm, a contact area between the seed crystal layer 12 and the sapphire substrate 11 is large, so that the sapphire substrate 11 tend to be bowed due to difference of thermal expansion coefficient and lattice constant between sapphire and the semiconductor layer of a III-V group compound of the nitride system, which results in high dislocation defect density in a region over the opening part 12A. Whereas, if that the width of the crystalline part 12A is less than 2 μm, the contact area between the crystalline part 12A and the sapphire substrate 11 is too small, then the crystalline part 12A is easy to strip from the sapphire substrate 11 while growing the crystal, at the same time, difficulties in production are caused. Therefore, the width of the crystalline part 12B is preferably more than 2 μm.

In case that the sapphire substrate 11 is bowed, each of layers made of the sapphire substrate 11 or the semiconductor of the III-V group compound of the nitride system is cracked, thereby stability in a manufacturing process is seriously damaged. Temperature of a surface of the sapphire substrate (crystal grown surface temperature) is not stable when growing the semiconductor of the III-V group compound of the nitride system so that a composition of the semiconductor of the III-V group compound of the nitride system grown thereon becomes various depending on parts. As a result of this, controllability in a manufacturing process is lost.

The semiconductor laser diode 1 is mounted on a heat sink through a submount as a semiconductor light-emitting device. At this moment, if the bowing of the sapphire substrate 11 and accompanying by this, the bowing of each of layers made of the semiconductor of the III-V group compound of the nitride system are prevented, adhesion among the submount, the heat sink, and the semiconductor laser diode 1 increases, thereby, heat generated by the semiconductor laser diode 1 when actuating is dissipated effectively. Accordingly, a rise in a threshold current of the semiconductor laser diode 1 caused or decrease in radiative output by thermal interference can be prevented. As a result of this, high quality can be maintained for long hours and long life can be attained on the semiconductor laser diode 1.

As described above, the width of the crystalline part of the seed crystal layer and the width of opening part are appropriately selected, which can provides the radiative part in a part where there is less crystal defects such as penetration dislocation (preferably, a region corresponding to L₂/4 shown as reference R in FIG. 7) and further, can be obtained longer life on the semiconductor laser diode 1.

### (EXAMPLES)

Further, specific examples of the present invention will be explained in detailed.

### (Examples 1-3)

Initially, a substrate made of sapphire was prepared and after cleaning was carried out thereon at 1050° C. in a hydrogen gas atmosphere, with a MOCVD method, a growth layer for a seed crystal layer was grown 2 μm, further, on the growth layer for a seed crystal layer, with a CVD method, an insulating film made of silicon nitride was formed.

Following this, a photoresist film was formed on the insulating film. A plurality of stripe-shaped pattern was formed parallel to a longitudinal direction of a region where a p-side electrode to be formed. Then, RIE was carried out with the pattern-formed photoresist film as a mask to remove the insulating film selectively. After this, the photoresist film was removed.

After removing the photoresist film, RIE was carried out with the insulating film as a mask to remove parts where the growth layer for the seed crystal layer and a growth layer for a buffer layer are uncovered with the insulating film sequentially. This formed a seed crystal layer having a crystalline part and an opening part. Then, in a like manner, with insulating film as a mask, RIE was carried out with chlorine etching gas to remove parts where the sapphire substrate was uncovered with the insulating film, thereby forming a concave part communicatively connected to the opening part in the sapphire substrate. At this moment, the sapphire substrate was respectively etched 70 nm, 100 nm, and 200 nm in Examples 1,2 and 3.

After forming the concave part in the sapphire substrate, etching was carried out to remove the insulating film. With the MOCVD method, n-type GaN doped silicon from the crystalline part of the seed crystal layer was grown 5 μm, which formed the n-side contact layer.

Then, on the n-side contact layer, with the MOCVD method, an n-type clad layer, an n-type guide layer, an active layer, a p-type guide layer, a p-type clad layer and a p-side contact layer were formed sequentially. Specifically, the n-type clad layer was formed by growing n-type Al_{0.08}Ga_{0.92} N mixed crystal doped silicon 1.0 μm. The n-type guide layer was formed by growing n-type GaN 0.12 μm. The active layer was formed as follows. First, a barrier layer was formed by growing GaInN mixed crystal 7.0 nm and a well layer was formed by growing undope-GaInN mixed crystal 3.5 nm, these layers are stacked in 3 periods. The p-type guide layer was formed by growing p-type GaN doped magnesium 0.12 μm. The p-type clad layer was formed by growing p-type Al_{0.08}Ga_{0.92} N mixed crystal doped magnesium 0.5 μm. The p-side contact layer was formed by growing p-type GaN doped magnesium 0.1 μm.

When forming each of the layers with the MOCVD method, trimethylgallium was employed as a source gas of gallium, trimethylaluminum was employed as a source gas of aluminum, trimethylindium was employed as a source gas of indium, ammonia was employed as a source gas of nitride. Additionally, monosilane was employed as a source gas of silicon and bis═cycropentadienyl magnesium was employed as a source gas of magnesium.

After forming the p-side contact layer, the p-side contact layer, the p-type clad layer, p-type guide layer, the active layer, the n-type guide layer, the n-type clad layer and the n-side contact layer were etched sequentially to expose the n-side contact layer on the surface. Then, a mask was formed parallel to a longitudinal direction of a region the p-side electrode to be formed in a latter process. With the RIE method using the mask, a part of the p-side contact layer and the p-type clad layer were selectively etched to shape the top surface of the p-type clad layer and the p-side contact layer in a thin belt shape.

Following this, an insulating layer made of silicon dioxide was formed on a whole exposed surface on the substrate with a deposition method, and on the insulating layer, a resist film was formed. RIE was carried several times to cover regions except the surface of the p-side contact layer with the insulating layer.

Then, on the surface or in the vicinity of the surface of the p-side contact layer, paradium, platinum and gold were deposited sequentially to form the p-side electrode. An opening was formed on the n-side contact layer of the insulating layer. On the opening, titanium, aluminum, platinum and gold were deposited to form the n-side electrode. After this, the substrate was ground in a manner to be about 80 μm thickness. Finally, the substrate was cleaved vertical to a longitudinal direction of the p-side electrode in a predetermined width and a reflective mirror was formed in the cleavage surface. This achieved the semiconductor laser diodes of Examples 1-3.

As for Comparative example relative to the embodiment, the semiconductor laser diodes were produced in the same manner as the embodiment except in that the concave part was not formed in the sapphire substrate.

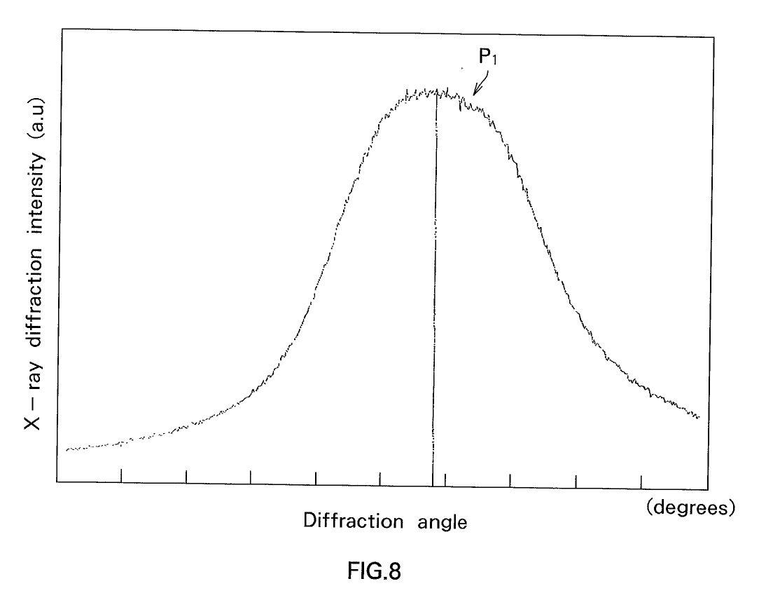

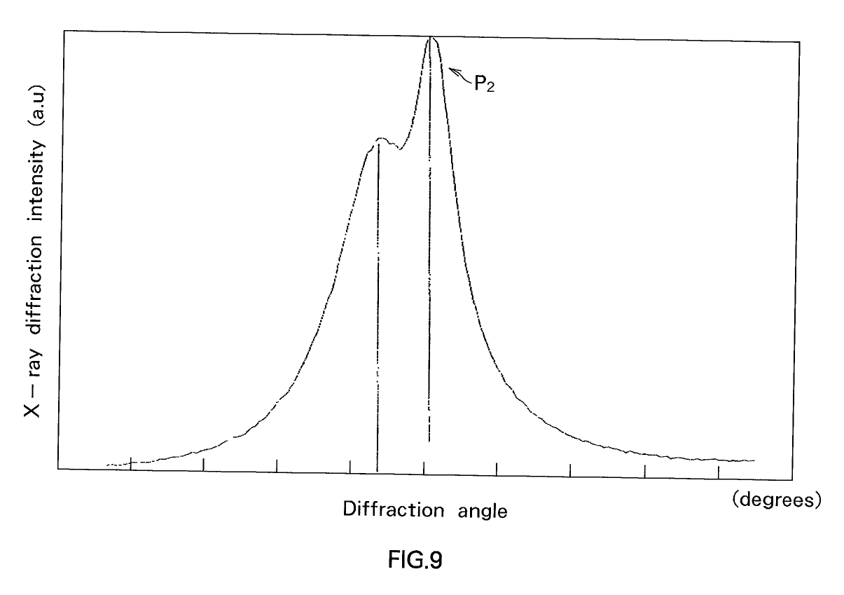

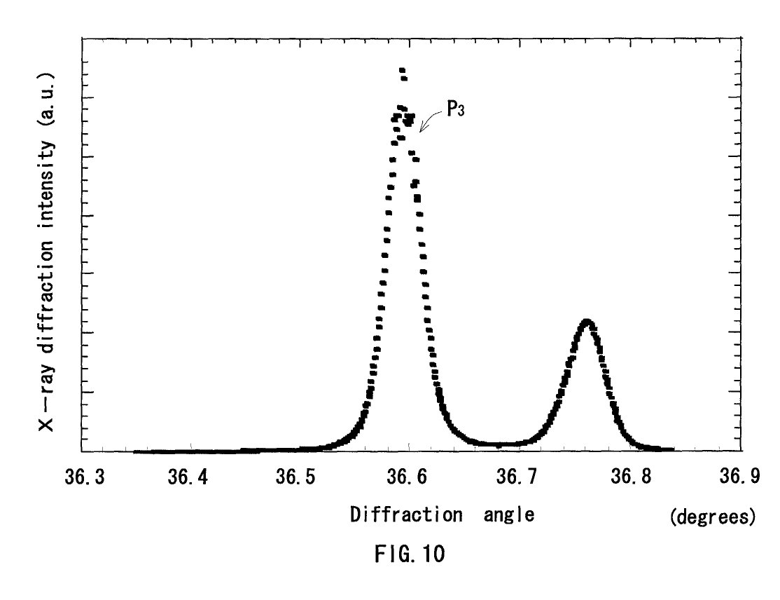

As the achieved semiconductor laser diodes of Example 1-3 and Comparative example, analysis was performed with an X-ray diffraction method. FIG. 8 shows a locking curb obtained with the X-ray diffraction of the achieved semiconductor laser diode in Example 1, and a half-value breadth of peak P₁ corresponding to the n-side contact layer was 689.3 arcsec. In Example 1, various peaks of crystal axes exist, which broadens a half-value breadth. Here, a vertical axis represents an X-ray diffraction intensity (arbitrary unit), a lateral axis represents an diffraction angle (unit; degree). FIG. 9 shows a locking curb obtained by the X-ray diffraction in Example 2 and double peak were observed in peak P₂ corresponding to the n-side contact layer. In Example 2, although peak P₂ had variation, a half value of breadth of one peak was narrower than the achieved half value of breadth in Example 1, and in addition, crystallinity was much excellent than that in Example 1. FIG. 10 shows a locking curb obtained by the X-ray diffraction of the semiconductor laser diode in Example 3, and a half value breadth of peak P₃ corresponding to the n-side contact layer was 155.4 arcsec. In Example 3, the half value breadth was narrow, and excellent crystal whose crystal orientation less changed, was grown.

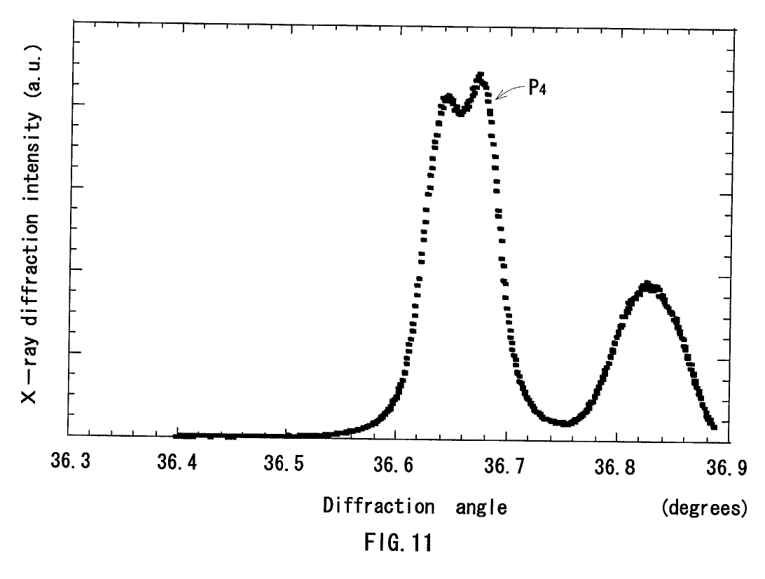

FIG. 11 shows a locking curb obtained by the X-ray diffraction of the semiconductor laser diode in Comparative example, and a half value breadth of peak P₄ corresponding to the n-side contact layer was 200 arcsec. Besides this, fracture was also observed. That is, crystallinity was relatively poor compared to that of the Examples.

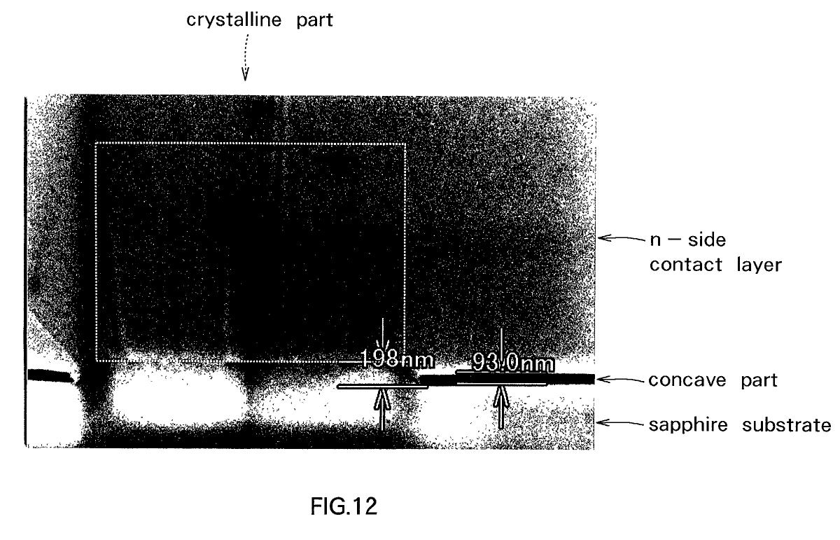

As for the achieved semiconductor laser diode in Example 3, with a scanning electron microscope (SEM), the concave part of the sapphire substrate, the seed crystal layer and the n-side contact layer were observed. FIG. 12 is a picture taken by SEM, and the crystalline part is a part surrounded by a dotted line. A depth of the concave part was 198 nm, if an error resulting from measurement accuracy were taken into consideration, substantially 200 nm. The concave part and the n-side contact layer are alienated, hence, there were gaps about 93 nm. In the lateral growth region corresponding to the concave part, although penetration dislocation less existed, it existed in a general center of the meeting part, excellent crystallinity could be obtained.

As the above-mentioned results, if the concave part communicatively connected to the opening part are formed in a region corresponding to the opening part of the seed crystal layer of the sapphire substrate, each of the lateral grown crystal meets each other, which attains a flat grown surface. In addition, if the depth of the concave part is determined as equal to or more than 100 nm, quality of the crystal grown from the crystalline part of the seed crystal layer can be enhanced. If it is determined as equal to or more than 200 nm, such quality can be much enhanced.

Here, although an specific explanation is omitted, in case that the n-side contact layer, the n-type clad layer, the n-type guide layer, the active layer, the p-type guide layer, the p-type clad layer and the p-side contact layer are grown by other semiconductors of the III-V group compound of the nitride system doped at least one kind element among the III group element and nitride, the same results are achieved.

As described above, the present invention was described by referring the embodiments and examples. However, the present invention is not limited by the above-mentioned embodiments and examples, many verifications and modifications are possible. For example, in the above-mentioned embodiments, the growth layer for a seed crystal layer, the contact layer and the guide layer were formed of GaN, the clad layer was formed of AlGaN mixed crystal and the active layer was formed of InGaN mixed crystal. These layers may be formed of other semiconductors of the III-V group compound of the nitride system containing at least one kind element among the III group element, and nitride.

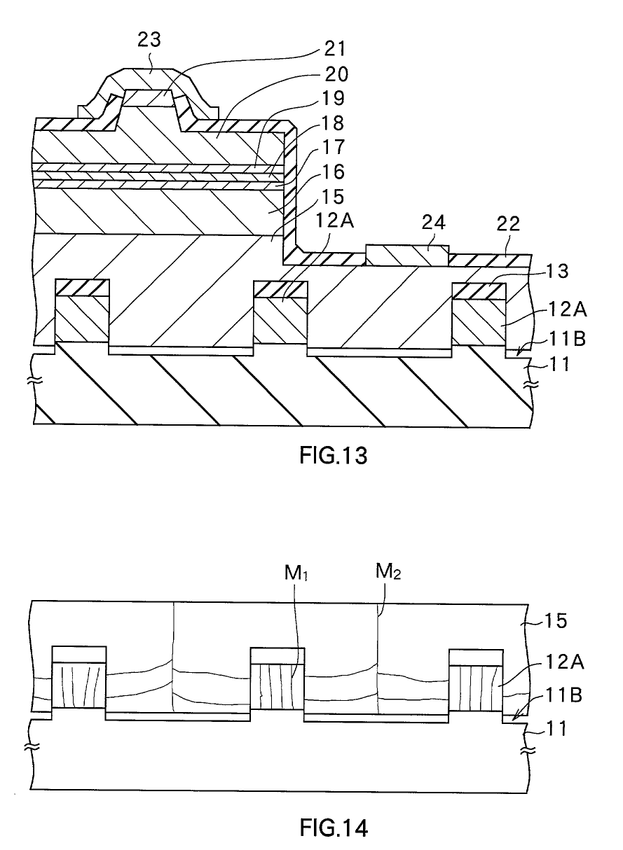

In the above-mentioned embodiments, after removing the insulating film 13, the n-side contact layer 15 was formed. However, as shown in FIG. 13, the n-side contact layer may be formed without removing the insulating film 13 on the seed crystal layer 12 (the crystalline part 12A). This shields penetration dislocation M₁ with the insulating film 13 to prevent propagation of penetration dislocation M₁ from the seed crystal layer 12. Accordingly, in the n-side contact layer 15, besides penetration dislocation M₂ attributing to a meet, crystal defections hardly exist, and the semiconductor of the III-V group compound of the nitride system having excellent crystallinity on its top side can be obtained. However, when growing the n-side contact layer 15, materials comprising the insulating film 13 are mixed into the n-side contact layer 15 as impurity, which degrades characteristics of the semiconductor laser diode 1. For the reason of this, an suitable manufacturing method should be selected according to a purpose for use.

Further, in the above-mentioned embodiments, the case that, the semiconductor of the III-V group compound of a nitride system was formed with the MOCVD method was described. It can be formed with other vapor deposition methods such as a MBE (Molecular Beam Epitaxy) method, or a hideride vapor phase growth method. The hideride vapor deposition method is a vapor deposition method such that halide contributes to transportation or reaction.

In the above-mentioned embodiments, on the sapphire substrate 11, the seed crystal layer 12, the n-side contact layer 15, the n-type clad layer 16, the n-type guide layer 17, the active layer 18, the p-type guide layer 19, the p-type clad layer 20 and the p-side contact layer 21 were stacked sequentially. The invention can be applied to a semiconductor laser diode having other structures in a like manner. For instance, the n-type guide layer 17 and the p-type guide layer 19 may not be provided, and a buffer layer may be formed between the sapphire substrate 11 and the seed crystal layer 12. The buffer layer is made of the crystal of a semiconductor of a III-V group compound of a nitride system close to amorphous and has a center role to grow the growth layer 12a for a seed crystal layer.

Furthermore, in the embodiments, a part of the p-type clad layer 20 and the p-side contact layer 21 were shaped in a thin belt shape extending in <11-20> directions of the sapphire substrate 11 for electric current restriction. However, it may be shaped as a thin belt shape extending in <11-100> directions of the sapphire substrate, or other structures maybe used for electric current restriction. In the embodiments, the semiconductor laser diode 1, which is a ridge waveguide type was described. The ridge waveguide type is a combination of a gain waveguide type and a refractive intensity waveguide type. A semiconductor laser diode of the gain waveguide type and a semiconductor laser diode of the refractive intensity waveguide type can be also applied.

Additionally, in the embodiments, the semiconductor laser diode 1 was described as a semiconductor device. The present invention can be applied to other semiconductor devices such as a light emitting diode or a field effect transistor.

As has been mentioned above, in a semiconductor device according to the present invention, a concave part is provided in regions corresponding to an opening part of a first crystal layer in a substrate made of sapphire. This can restrict density of penetration dislocation in a semiconductor layer, along with this, prevent change of a crystal orientation and enhance crystallinity of the semiconductor layer made of a semiconductor of a III-V group compound of a nitride system. Thereby, device quality can be enhanced. Especially, a semiconductor device according to claim 2, a depth of concave part is determined as equal to or more than 100 nm, which results in devices with higher quality.

Specifically, in a semiconductor device according to one aspect of the present invention, a width direction of a crystalline part of the first crystal layer is less than 4 μm, and a width direction of an opening part is equal to or less than 12 μm, which increases regions excellent in crystallinity having low density of penetration dislocation in the semiconductor layer, and enhances device characteristics.

More specifically, in a semiconductor device according to another aspect of the invention, a radiative range is formed corresponding to the opening part or to a region between the crystalline part and the meeting part. This results in prevention of degradation caused by applying voltage, which can obtain long life. At the same time, a ratio of a non-radiative recombination due to penetration dislocation and the like can be smaller and light emission efficiency can be increased.

Further specifically, in a method of manufacturing a semiconductor device according to still another aspect of the present invention, a concave part communicatively connected to the opening part are formed in a region corresponding to the opening part of the first crystal layer of the substrate made of sapphire in order to form a second crystal layer from the crystalline part of the first crystal layer. This can obtain decrease of density of penetration dislocation in the semiconductor layer. For the reason of this, even if in case that the second crystal layer is grown in a lateral direction from the crystalline part, the second crystal layer and the substrate does not contact each other and density of penetration dislocation in the semiconductor layer can decrease.

Specifically, in a method of manufacturing a semiconductor device according to further another aspect of the present invention, an opening is formed in a growth layer such that a length in a width direction of the crystalline part of the first crystal layer is less than 4 μm and a length in a width direction of the opening part is equal to or more than 12 μm, which can obtain a semiconductor device with excellent device characteristics easily. Besides this, in a method of manufacturing a semiconductor device according to the present invention, a radiative range is formed corresponding to a part from a boundary surface between the opening part and the crystalline part to half of a width of the opening part or quarter of the opening part, which can obtains a semiconductor device having high radiative characteristics.

Obviously many modifications and variations of the present invention are possible in the light of the above teachings. It is therefore to be understood that within the scope of the appended claims the invention may be practiced otherwise than as specifically described.

What is claimed is:

1. A semiconductor device including a semiconductor layer made of a semiconductor of a III-V group compound of a nitride system containing at least one kind element among a III group element and nitride among a V group element on a side of a substrate made of sapphire (Al₂O₃), comprising:
the semiconductor layer including a first crystal layer having a crystalline part made of a crystal of the semiconductor of the III-V group compound of the nitride system and an opening part, and a second crystal layer provided in a manner of covering the crystalline part of the first crystal layer; and
the substrate including a concave part in a region corresponding to the opening part of the first crystal layer.

2. A semiconductor device according to claim 1, wherein a depth of the concave part of the substrate is equal to or more than 100 nm.

3. A semiconductor device according to claim 2, wherein the depth of the concave part of the substrate is equal to or more than 200 nm.

4. A semiconductor device according to claim 1, wherein a base surface of the concave part of the substrate and the semiconductor layer are alienated each other.

5. A semiconductor device according to claim 1, wherein a length in a width direction of the crystalline part is less than 4 μm and a length in a width direction of the opening part is equal to or less than 12 μm.

6. A semiconductor device according to claim 5, wherein the length in the width direction of the opening part is more than 8 μm.

7. A semiconductor device according to claim 5, wherein the length in the width direction of the crystalline part is more than 2 μm.

8. A semiconductor device according to claim 1, wherein the semiconductor layer further has an active layer, the active layer has a radiative range corresponding to the opening part.

9. A semiconductor device according to claim 8, wherein the second crystal layer includes a meeting part formed by growing in a lateral direction; and
the active layer has the radiative range corresponding to a region between the crystalline part and the meeting part.

10. A method of manufacturing a semiconductor device formed by growing a semiconductor of a III-V group compound of a nitride system containing at least one kind element among a III group element and nitride (N) among a V group element, comprising steps of:
forming a growth layer by growing a crystal of the semiconductor of the III-V group compound of the nitride system on the substrate;
forming a first crystal layer having a crystalline part and an opening part by selectively removing the growth layer in order to form the opening;
forming a concave part communicatively connected to the opening part on the substrate by selectively removing a region corresponding to the opening part of the first crystal layer of the substrate; and
forming a second crystal layer by growing the crystal of the semiconductor of the III-V group compound of the nitride system from the crystalline part of the first crystal layer.

11. A method of manufacturing a semiconductor device according to claim 10, wherein the concave part whose depth is equal to or more than 100 nm, is formed in the substrate.

12. A method of manufacturing a semiconductor device according to claim 10, wherein in the step of forming the first crystal layer, the opening is formed in a manner that a length in a width direction of the crystalline part is less than 4 μm and a length in a width direction of the opening part is equal to or less than 12 μm.

13. A method of manufacturing a semiconductor device according to claim 10 comprises a step of forming an active layer having a radiative region corresponding to a region from a boundary surface between the opening part and the crystalline part to half of the width of the opening part.

14. A method of manufacturing a semiconductor device according to claim 13, wherein an active layer is formed, and the active layer has the radiative range corresponding to a region from the boundary surface between the opening part and the crystalline part to quarter of the width of the opening part.
